(19) United States
(12) Patent Application Publication
(10) Pub. No.: US 2025/0203918 A1
(43) Pub. Date: Jun. 19, 2025

(54) GATE CUT STRUCTURE FOR TRANSISTORS

(71) Applicant: International Business Machines Corporation, Armonk, NY (US)

(72) Inventors: Chanro Park, Clifton Park, NY (US); Ruilong Xie, Niskayuna, NY (US); Min Gyu Sung, Latham, NY (US); Julien Frougier, Albany, NY (US); Juntao Li, Cohoes, NY (US)

(21) Appl. No.: 18/543,734

(22) Filed: Dec. 18, 2023

(51) Int. Cl. H01L 29/78; H01L 21/8234; H01L 27/088; H01L 29/417

(52) U.S. Cl. CPC H10D 30/6217; H10D 30/6219; H10D 64/258; H10D 84/834; H10D 84/013; H10D 84/0158; H10D 84/038

(57) ABSTRACT

A semiconductor device includes at least one transistor including a gate structure and a source/drain region, and a source/drain contact structure disposed on the source/drain region. The source/drain contact structure includes a first metal layer and second metal layer disposed on the first metal layer, wherein the second metal layer includes a different material than the first metal layer and is disposed on an uppermost surface of the first metal layer. A gate cut portion is disposed through a part of the gate structure, wherein the source/drain contact structure is disposed on a side of the gate cut portion.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming a gate cut structure for a semiconductor device.

In one embodiment, a semiconductor device includes at least one transistor including a gate structure and a source/drain region, and a source/drain contact structure disposed on the source/drain region. The source/drain contact structure includes a first metal layer and second metal layer disposed on the first metal layer, wherein the second metal layer includes a different material than the first metal layer and is disposed on an uppermost surface of the first metal layer. A gate cut portion is disposed through a part of the gate structure, wherein the source/drain contact structure is disposed on a side of the gate cut portion.

In another embodiment, a semiconductor device includes a gate cut portion disposed through a gate structure, and a source/drain contact structure disposed around the gate cut portion, wherein the source/drain contact structure includes a first metal layer and second metal layer disposed on the first metal layer. The second metal layer includes a different material than the first metal layer and is disposed on an uppermost surface of the first metal layer.

In another embodiment, a semiconductor device includes a first gate cut portion disposed through a first gate structure, and a second gate cut portion disposed through a second gate structure. A source/drain contact structure is disposed around the first gate cut portion and the second gate cut portion, wherein the source/drain contact structure includes a first metal layer and second metal layer disposed on the first metal layer. The second metal layer includes a different material than the first metal layer and is disposed on an uppermost surface of the first metal layer.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with lines X₁-X₁′, X₂-X₂′, Y₁-Y₁′ and Y₂-Y₂′ on which the cross-sectional views of FIGS. 2A-10D are based, according to an embodiment of the invention.

FIG. 2A depicts a first cross-sectional view corresponding to the line X₁-X₁′ in FIG. 1 illustrating the semiconductor structure following formation of replacement metal gate (RMG) regions and self-aligned contact (SAC) cap layers, according to an embodiment of the invention.

FIG. 2B depicts a second cross-sectional view corresponding to the line X₂-X₂′ in FIG. 1 illustrating the semiconductor structure following formation of RMG regions and SAC cap layers, according to an embodiment of the invention.

FIG. 2C depicts a third cross-sectional view corresponding to the line Y₁-Y₁′ in FIG. 1 illustrating the semiconductor structure following formation of RMG regions and SAC cap layers, according to an embodiment of the invention.

FIG. 2D depicts a fourth cross-sectional view corresponding to the line Y₂-Y₂′ in FIG. 1 illustrating the semiconductor structure following formation of RMG regions and SAC cap layers, according to an embodiment of the invention.

FIG. 3A depicts a first cross-sectional view corresponding to the line X₁-X₁′ in FIG. 1 following formation of a dielectric layer on the structure of FIG. 2A, according to an embodiment of the invention.

FIG. 3B depicts a second cross-sectional view corresponding to the line X₂-X₂′ in FIG. 1 following formation of a dielectric layer on the structure of FIG. 2B, according to an embodiment of the invention.

FIG. 3C depicts a third cross-sectional view corresponding to the line Y₁-Y₁′ in FIG. 1 following formation of a dielectric layer on the structure of FIG. 2C, and according to an embodiment of the invention.

FIG. 3D depicts a fourth cross-sectional view corresponding to the line Y₂-Y₂′ in FIG. 1 following formation of a dielectric layer on the structure of FIG. 2D, according to an embodiment of the invention.

FIG. 4A depicts a first cross-sectional view corresponding to the line X₁-X₁′ in FIG. 1 following formation of openings for source/drain contacts, according to an embodiment of the invention.

FIG. 4B depicts a second cross-sectional view corresponding to the line X₂-X₂′ in FIG. 1 following formation of openings for source/drain contacts, according to an embodiment of the invention.

FIG. 4C depicts a third cross-sectional view corresponding to the line Y₁-Y₁′ in FIG. 1 following formation of openings for source/drain contacts, according to an embodiment of the invention.

FIG. 4D depicts a fourth cross-sectional view corresponding to the line Y₂-Y₂′ in FIG. 1 following formation of openings for source/drain contacts, according to an embodiment of the invention.

FIG. 5A depicts a first cross-sectional view corresponding to the line X₁-X₁′ in FIG. 1 following formation of source/drain contacts, according to an embodiment of the invention.

FIG. 5B depicts a second cross-sectional view corresponding to the line X₂-X₂′ in FIG. 1 following formation of source/drain contacts, according to an embodiment of the invention.

FIG. 5C depicts a third cross-sectional view corresponding to the line Y₁-Y₁′ in FIG. 1 following formation of source/drain contacts, according to an embodiment of the invention.

FIG. 5D depicts a fourth cross-sectional view corresponding to the line Y₂-Y₂′ in FIG. 1 following formation of source/drain contacts, according to an embodiment of the invention.

FIG. 6A depicts a first cross-sectional view corresponding to the line X₁-X₁′ in FIG. 1 following recessing of source/drain contacts, according to an embodiment of the invention.

FIG. 6B depicts a second cross-sectional view corresponding to the line X₂-X₂′ in FIG. 1 following recessing of source/drain contacts, according to an embodiment of the invention.

FIG. 6C depicts a third cross-sectional view corresponding to the line Y₁-Y₁′ in FIG. 1 following recessing of source/drain contacts, according to an embodiment of the invention.

FIG. 6D depicts a fourth cross-sectional view corresponding to the line Y₂-Y₂′ in FIG. 1 following recessing of source/drain contacts, according to an embodiment of the invention.

FIG. 7A depicts a first cross-sectional view corresponding to the line X₁-X₁′ in FIG. 1 following deposition of a metal layer on the recessed source/drain contacts, according to an embodiment of the invention.

FIG. 7B depicts a second cross-sectional view corresponding to the line X₂-X₂′ in FIG. 1 following deposition of a metal layer on the recessed source/drain contacts, according to an embodiment of the invention.

FIG. 7C depicts a third cross-sectional view corresponding to the line Y₁-Y₁′ in FIG. 1 following deposition of a metal layer on the recessed source/drain contacts, according to an embodiment of the invention.

FIG. 7D depicts a fourth cross-sectional view corresponding to the line Y₂-Y₂′ in FIG. 1 following deposition of a metal layer on the recessed source/drain contacts, according to an embodiment of the invention.

FIG. 8A depicts a first cross-sectional view corresponding to the line X₁-X₁′ in FIG. 1 following lithography mask formation, according to an embodiment of the invention.

FIG. 8B depicts a second cross-sectional view corresponding to the line X₂-X₂′ in FIG. 1 following lithography mask formation, according to an embodiment of the invention.

FIG. 8C depicts a third cross-sectional view corresponding to the line Y₁-Y₁′ in FIG. 1 following lithography mask formation, according to an embodiment of the invention.

FIG. 8D depicts a fourth cross-sectional view corresponding to the line Y₂-Y₂′ in FIG. 1 following lithography mask formation, according to an embodiment of the invention.

FIG. 9A depicts a first cross-sectional view corresponding to the line X₁-X₁′ in FIG. 1 following formation of trenches for gate cut portions, according to an embodiment of the invention.

FIG. 9B depicts a second cross-sectional view corresponding to the line X₂-X₂′ in FIG. 1 following formation of trenches for gate cut portions, according to an embodiment of the invention.

FIG. 9C depicts a third cross-sectional view corresponding to the line Y₁-Y₁′ in FIG. 1 following formation of trenches for gate cut portions, according to an embodiment of the invention.

FIG. 9D depicts a fourth cross-sectional view corresponding to the line Y₂-Y₂′ in FIG. 1 following formation of trenches for gate cut portions, according to an embodiment of the invention.

FIG. 10A depicts a first cross-sectional view corresponding to the line X₁-X₁′ in FIG. 1 following deposition of dielectric material and planarization to form gate cut portions, according to an embodiment of the invention.

FIG. 10B depicts a second cross-sectional view corresponding to the line X₂-X₂′ in FIG. 1 following deposition of dielectric material and planarization to form gate cut portions, according to an embodiment of the invention.

FIG. 10C depicts a third cross-sectional view corresponding to the line Y₁-Y₁′ in FIG. 1 following deposition of dielectric material and planarization to form gate cut portions, according to an embodiment of the invention.

FIG. 10D depicts a fourth cross-sectional view corresponding to the line Y₂-Y₂′ in FIG. 1 following deposition of dielectric material and planarization to form gate cut portions, according to an embodiment of the invention.

### DETAILED DESCRIPTION

Illustrative embodiments of the invention may be described herein in the context of illustrative methods for forming a gate cut structure for a semiconductor device where a source/drain contact structure formed around the gate structure includes a first metal layer and second metal cap layer, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation complementary FET (CFET) devices may be used. CFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. CFET structures provide improved track height scaling, leading to structural gains (e.g., such as 30-40% structural gains for different types of devices, such as logic devices, static random-access memory (SRAM) devices, etc.). In CFET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation CFET devices.

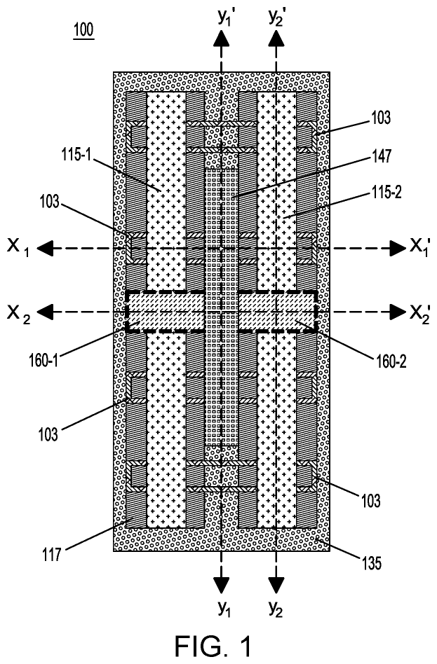

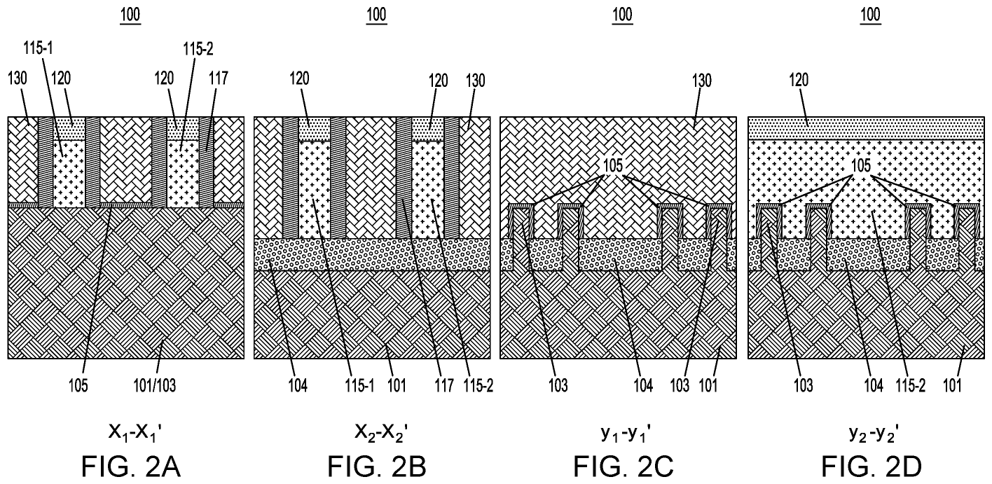

Referring to FIGS. 1 and 2A-2D, a semiconductor structure 100 includes a semiconductor substrate 101 including semiconductor material including, but not limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or other like semiconductor. In addition, multiple layers of the semiconductor materials can be used as the semiconductor material of the substrate. The semiconductor substrate 101 can be a bulk substrate or a semiconductor-on-insulator substrate such as, but not limited to, a silicon-on-insulator (SOI), silicon-germanium-on-insulator (SGOI) or III-V-on-insulator substrate including a buried insulating layer, such as, for example, a buried oxide, nitride layer or aluminum oxide.

Fins, such as fins 103, can be formed by patterning a semiconductor layer into the fins 103. The semiconductor layer can include, but is not necessarily limited to, Si, SiGe or III-V materials, and may be epitaxially grown. According to an embodiment, a hardmask (not shown) including, for example, a dielectric material, such as silicon nitride (SiN) is formed on portions of the semiconductor layer that are to be formed into the fins 103. The fin patterning can be done by various patterning techniques, including, but not necessarily limited to, directional etching and/or a sidewall image transfer (SIT) process, for example. The SIT process includes using lithography to form a pattern referred to as a mandrel. The mandrel material can include, but is not limited to, amorphous silicon or amorphous carbon. After the mandrel formation, a conformal film can be deposited and then followed by an etchback. The conformal film will form spacers at both sides of the mandrel. The spacer material can include, but is not limited to, oxide or SiN. After that, the mandrel can be removed by reactive ion etching (RIE) processes. As a result, the spacers will have half the pitch of the mandrel. In other words, the pattern is transferred from a lithography-defined mandrel to spacers, where the pattern density is doubled. The spacer pattern can be used as the hardmask to form the fins by RIE processes. Alternatively, fin patterning can be done by any other suitable patterning technique, including but not limited to, lithography (e.g., extreme ultraviolet (EUV)) in conjunction with RIE, self-aligned double patterning (SADP), self-aligned multiple patterning (SAMP), and/or self-aligned quadruple patterning (SAQP)). While embodiments of the present invention describe channel regions as fins, the embodiments are not necessarily limited to fin channel regions, and may include nanowire channel regions. In addition, although four fins 103 are shown in the figures for ease of explanation, more or less than four fins can be formed.

A lower dielectric layer 104 including, but not necessarily limited to silicon oxide (SiOₓ), where x is, for example, 2 in the case of silicon dioxide (SiO₂), or 1.99 or 2.01, low-temperature oxide (LTO), high-temperature oxide (HTO), flowable oxide (FOX), silicon oxycarbide (SiOC), silicon oxycarbonitride (SiOCN) or some other dielectric, is formed on the semiconductor substrate 101 and around the fins 103. The dielectric material can be deposited using deposition techniques including, but not limited to, chemical vapor deposition (CVD), plasma enhanced CVD (PECVD), radio-frequency CVD (RFCVD), physical vapor deposition (PVD), atomic layer deposition (ALD), molecular layer deposition (MLD), molecular beam deposition (MBD), pulsed laser deposition (PLD), liquid source misted chemical deposition (LSMCD), and/or sputtering, The lower dielectric layer 104 defines one or more isolation regions, such as, for example, shallow trench isolation (STI) regions.

Prior to replacement metal gate (RMG) processing, sacrificial gate portions (not shown) are formed on and around the fins 103. The sacrificial gate portions include, but are not necessarily limited to, amorphous silicon (a-Si). The sacrificial gate portions are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess sacrificial gate material, and pattern the deposited layer.

Gate spacers 117 are positioned on opposite lateral sides of the sacrificial gate portions, which are eventually replaced by gate structures 115-1 and 115-2 (collectively “gate structures 115”). The gate spacers 117 are formed from a dielectric material including, but not necessarily limited to, a nitride, such as, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) or other dielectric. The gate spacers 117 can be formed by any suitable techniques such as deposition followed by directional etching. Deposition may include, but is not limited to, ALD or CVD. Directional etching may include but is not limited to RIE.

In an illustrative embodiment, fins 103 where source/drain regions 105 are to be formed are exposed. The source/drain regions 105 are epitaxially grown in epitaxial growth processes from the upper portions of the fins 103.

According to a non-limiting embodiment of the present invention, the conditions of the epitaxial growth process for the source/drain regions 105 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr.

The source/drain regions 105 may be suitably doped, such as by using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI).

In non-limiting illustrative embodiments, the source/drain regions 105 can include in-situ phosphorous doped (ISPD) silicon or Si:C for n-type devices, or in-situ boron doped (ISBD) silicon germanium for p-type devices, at concentrations of about 1×10¹⁹/cm³ to about 3×10²¹/cm³. By “in-situ,” it is meant that the dopant that dictates the conductivity type of the doped layer is introduced during the process step, e.g., epitaxial deposition, which forms the doped layer.

An inter-layer dielectric (ILD) layer 130 is deposited to fill in portions on and around the source/drain regions 105 and the sacrificial gate portions, which are eventually replaced by the gate structures 115. The ILD layer 130 is deposited using deposition techniques such as, for example, CVD, PECVD, RFCVD, PVD, ALD, MBD, PLD, and/or LSMCD, followed by a planarization process, such as, CMP to remove excess portions of the ILD layer 130 deposited on top of the sacrificial gate portions and gate spacers 117. The ILD layer 130 may include, for example, SiOₓ, SiOC, SiOCN or some other dielectric material.

The sacrificial gate portions are selectively removed to create vacant areas where gate structures 115 and self-aligned contact (SAC) cap layers 120 will be formed in place of the sacrificial gate portions. The selective removal can be performed using, for example, hot ammonia to remove sacrificial gate portions. In illustrative embodiments, each gate structure 115-1 and 115-2 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 115 each include a metal gate portion including a work-function metal (WFM) layer, including but not necessarily limited to, for a PFET, titanium nitride (TiN) or tantalum nitride (TaN), and for an NFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

The SAC cap layers 120 include, but are not necessarily limited to, silicon SiN, SiBN, SiBCN or SiOCN. According to an embodiment of the present invention, the SAC cap layers 120 are deposited using, for example, deposition techniques including, but not limited to, CVD, PECVD, RFCVD, PVD, ALD, MLD, MBD, PLD, LSMCD, sputtering, and/or plating, followed by a planarization process, such as, for example, CMP.

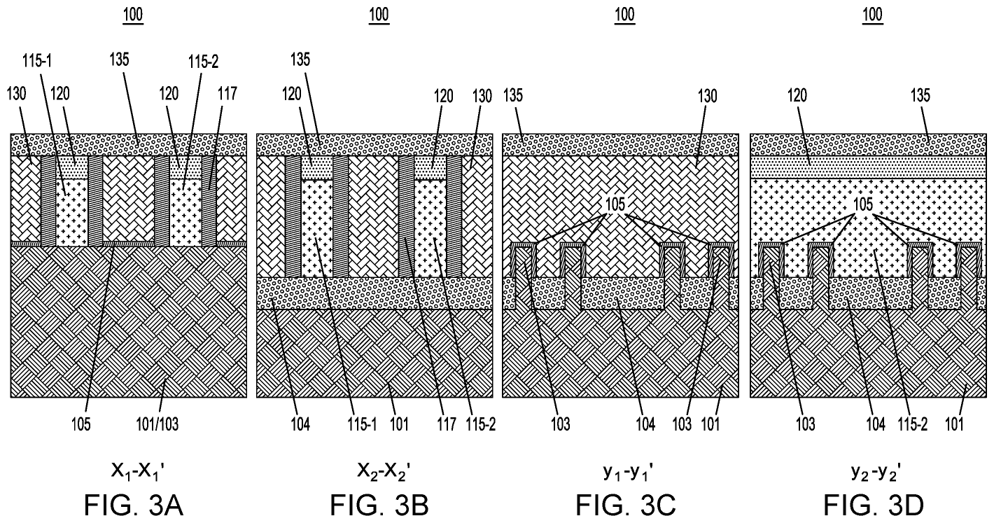

Referring to FIGS. 3A-3D, an additional dielectric layer 135 is deposited on the ILD layer 130. In illustrative embodiments, the additional dielectric layer 135 includes an oxide such as, but not necessarily limited to, SiOₓ. The additional dielectric layer 135 is thinner (smaller vertical thickness) than the ILD layer 130. The additional dielectric layer is deposited using deposition techniques such as, for example, CVD, PECVD, RFCVD, PVD, ALD, MBD, PLD, and/or LSMCD, which may be followed by a planarization process, such as, CMP.

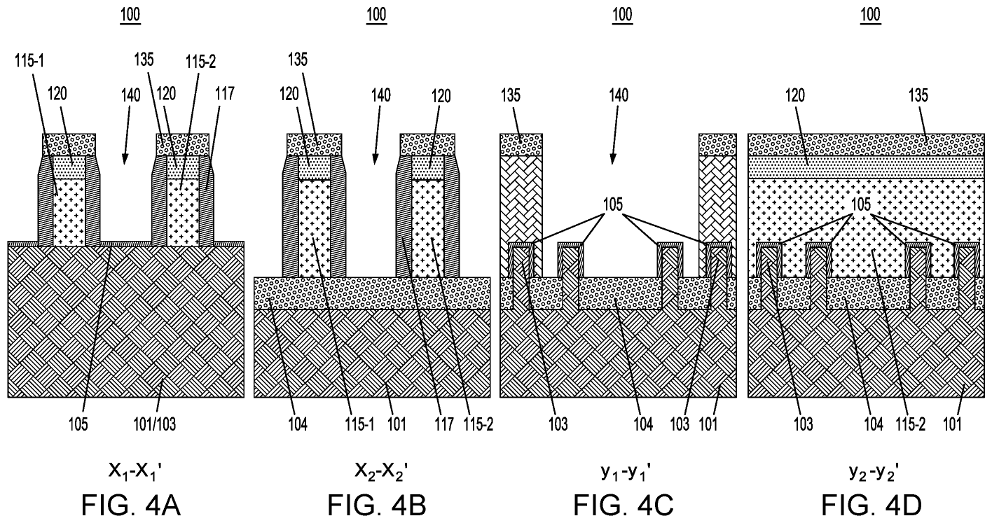

Referring to FIGS. 4A-4D, in order to form openings for source/drain contact structures, portions of the semiconductor structure 100 are masked (e.g., with a hardmask (not shown)). At unmasked portions corresponding to where the source/drain contact structures are to be formed, openings (e.g., contact trenches) 140 are formed by removing parts of the additional dielectric layer 135 and ILD layer 130 over the source/drain regions 105. In addition to exposing the source/drain regions 105, the removal exposes portions of the lower dielectric layer 104. The openings 140 are formed using, for example, a dry etching process using a RIE or ion beam etch (IBE) process, a wet chemical etch process or a combination of these etching processes.

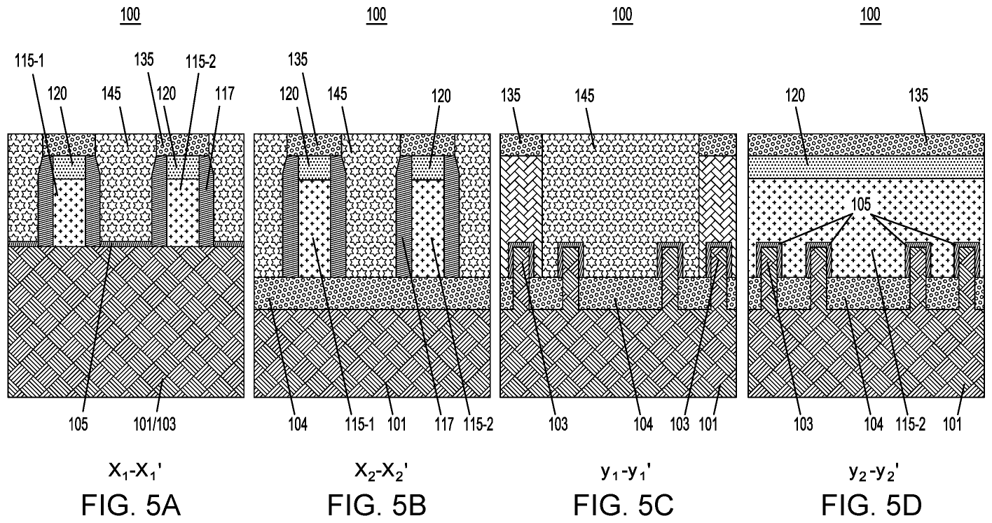

Referring to FIGS. 5A-5D, first metal layers 145 of source/drain contact structures are deposited in the openings 140. The first metal layers 145 include a low resistance conductor such as, but not necessarily limited to, copper tungsten or cobalt, and can be deposited using, for example, a deposition technique such as CVD, PECVD, RFCVD, PVD, ALD, MBD, PLD, LSMCD, sputtering and/or plating, followed by CMP. In an illustrative embodiment, the low resistance conductor is deposited on an optional metal liner layer, such as TiN.

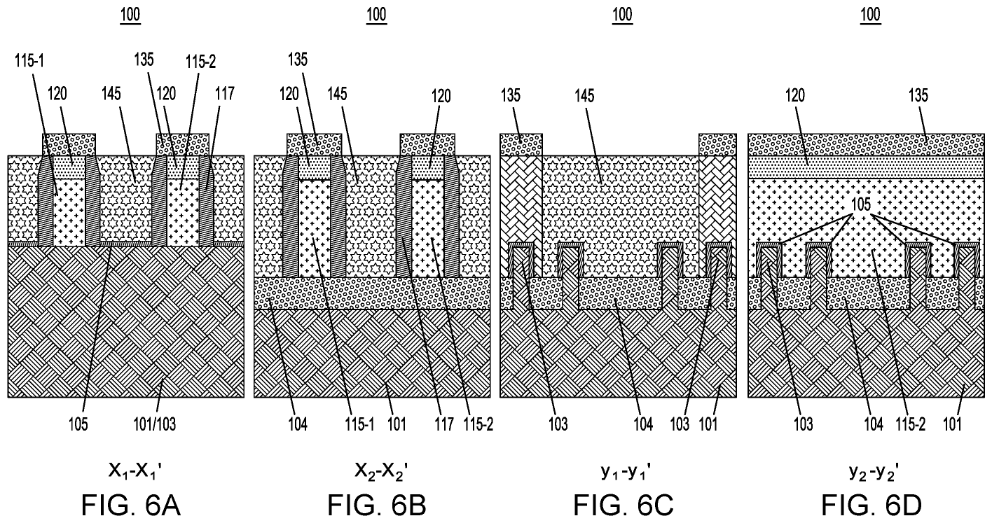

Referring to FIGS. 6A-6C, the first metal layers are recessed to a height were the uppermost surfaces of the first metal layers 145 are coplanar or substantially coplanar with the uppermost surfaces of the SAC cap layers 120 and the ILD layer 130. As shown in FIGS. 6A-6D, the first metal layers 145 are recessed between the remaining portions of the additional dielectric layer 135. The recessing is performed using a controlled removal process including, for example, isotropic plasma etching using SF₆ plasma or wet etching with mixture of H₂O, H₂O₂ and NH₄OH for tungsten.

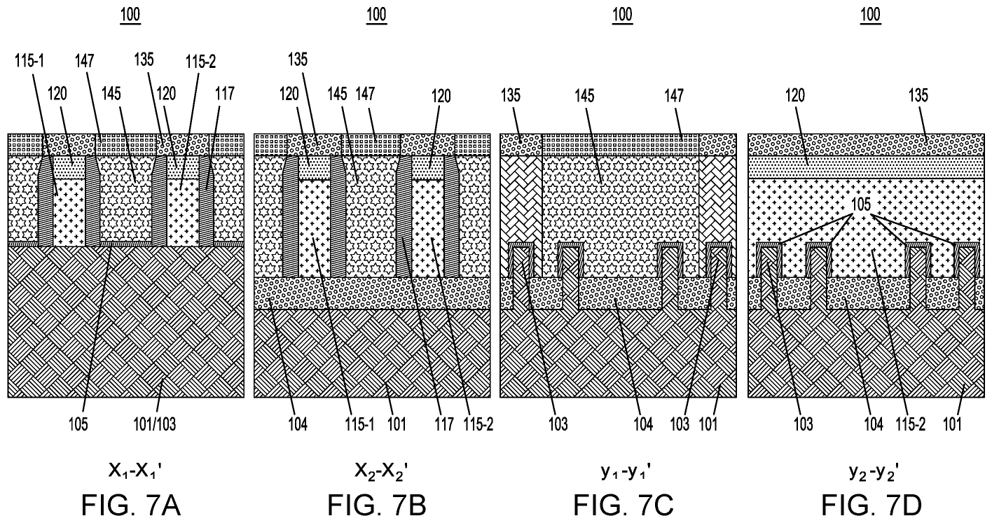

Referring to FIGS. 7A-7C, second metal layers 147 of the source/drain contact structures are deposited on the uppermost surfaces of the recessed first metal layers 145 to replace the removed portions of the first metal layers 145. The second metal layers 147 include a different material from that of the first metal layers 145 such as, ruthenium, and can be deposited using, for example, a deposition technique such as CVD, PECVD, RFCVD, PVD, ALD, MBD, PLD, LSMCD, sputtering and/or plating, followed by CMP. In an illustrative embodiment, the top surfaces of the second metal layers 147 are coplanar or substantially coplanar with top surfaces of the remaining portions of the additional dielectric layer 135. As can be seen, the second metal layers 147 are configured as cap layers on the uppermost surfaces of the first metal layers 145. The second metal layers 147 are thinner (smaller vertical thickness) than the first metal layers 145. As shown in FIGS. 7A-7D, the second metal layers 147 are formed between the remaining portions of the additional dielectric layer 135.

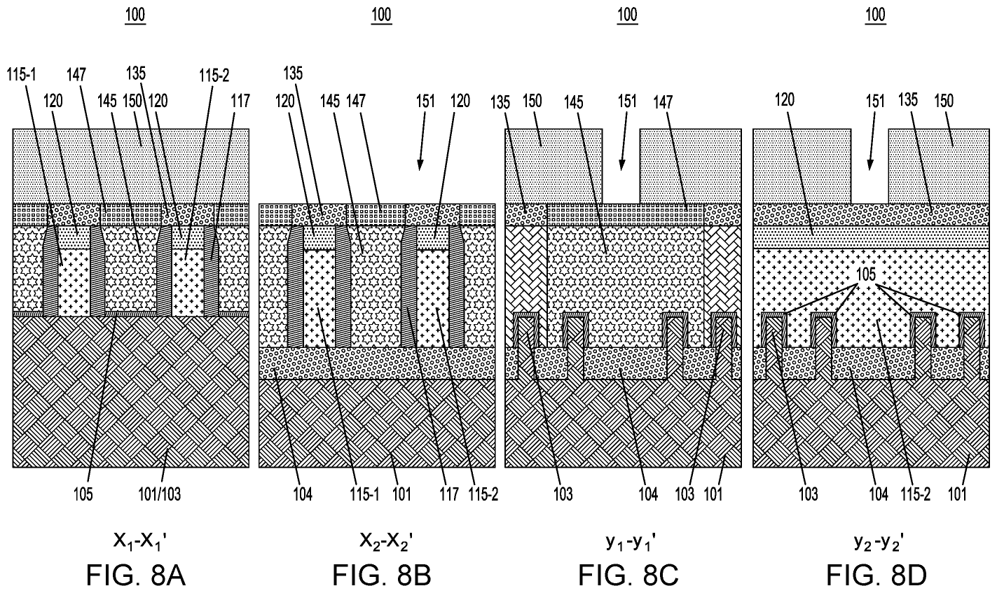

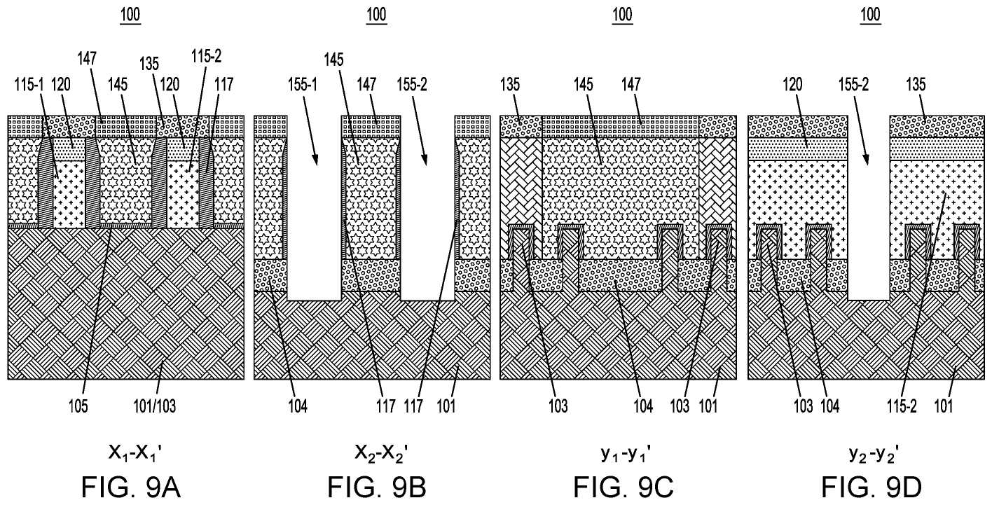

Referring to FIGS. 8A-8D, a mask 150 is formed on portions of the second metal layers 147 and on the remaining portions of the additional dielectric layer 135. The mask 150 includes, for example, a carbon-based layer deposited by CVD or by spin coating, and includes openings 151 corresponding to where gate cut portions are to be formed. Referring to FIGS. 1 and 9A-9D, portions of the SAC cap layers 120, the gate structures 115-1 and 115-2, gate spacers 117 and underlying lower dielectric layers 104 are removed to create openings 155-1 and 155-2 where the gate cut portions 160-1 and 160-2 are to be formed. In an illustrative embodiment, etching is performed with one or more etch chemistries that selectively remove materials of the SAC cap layers 120, the gate structures 115-1 and 115-2, gate spacers 117 and underlying lower dielectric layers 104 with respect to the materials of the second metal layers 147 and the first metal layers 145. For example, the one or more chemistries may etch SiO₂, SiN, W, TiN and TiC, but not Co or Ru. The one or more etch chemistries may include, for example, chlorine-based chemistry or fluorine-based chemistry or a mixture of chlorine-based chemistry and fluorine-based chemistry.

In an illustrative embodiment, since second metal layers 147 formed of ruthenium can only be removed by oxygen (O₂) plasma, the second metal layers 147 provide good etch selectivity with respect to the materials of SAC cap layers 120, the gate structures 115-1 and 115-2, gate spacers 117. As a result, the second metal layers 147 function as a mask to prevent etching of the underlying first metal layers 145. In addition, the one or more etch chemistries that are used to selectively remove materials of the SAC cap layers 120, the gate structures 115-1 and 115-2, gate spacers 117 and underlying lower dielectric layers 104 may also be designed to avoid removal of the first metal layers 145, which may be exposed if the gate spacers 117 are completely removed. In one or more embodiments, the gate spacers 117 may have a sufficient horizontal thickness to protect the first metal layers 145 during formation of the openings 155-1 and 155-2. As can be understood from FIGS. 8A-8D, the mask 150 covers portions of the additional dielectric layer 135 and underlying portions of the SAC cap layers 120 and gate structures 115-1 and 115-2 that are to remain and not be removed.

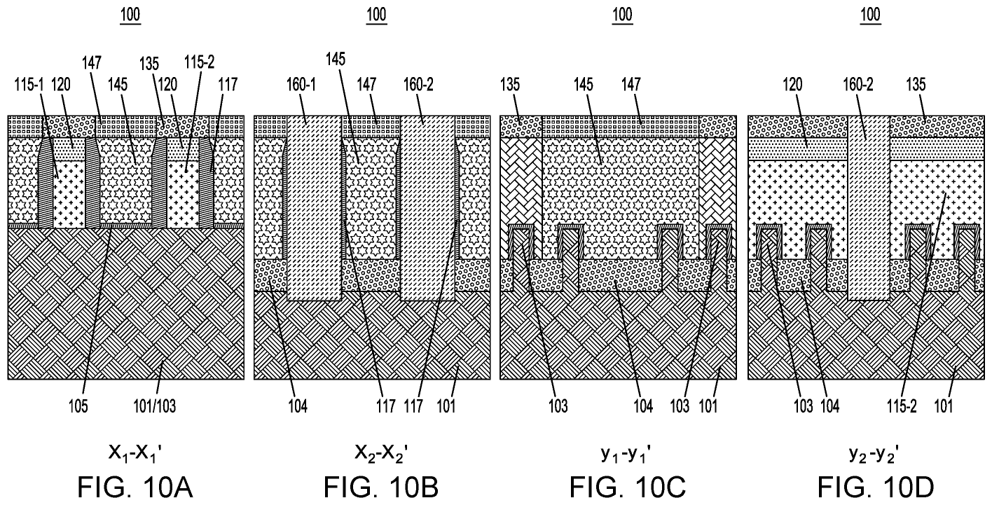

Referring to FIGS. 1 and 10A-10D, gate cut portions 160-1 and 160-2 respectively splitting the gate structures 115-1 and 115-2 into two portions isolated from each other are formed. Dielectric material is deposited in the openings 155-1 and 155-2 to form the gate cut portions 160-1 and 160-2. The dielectric material of the gate cut portions 160-1 and 160-2 is deposited using deposition techniques such as, for example, CVD, PECVD, RFCVD, PVD, ALD, MBD, PLD, and/or LSMCD, followed by a planarization process, such as, CMP such that the top surfaces of the gate cut portions 160-1 and 160-2 are coplanar with or substantially coplanar with the top surfaces of the second metal layers 147 and/or the remaining portions of the additional dielectric layer 135. The dielectric material of the gate cut portions 160-1 and 160-2 may include, but is not necessarily limited to, SiN, SiC, SiON, SiOC, SiCN, BN, SiBN, SiBCN, SiOCN, SiOₓ or some other dielectric.

The source/drain contact structures including the first and second metal layers 145 and 147 are disposed on source/drain regions 105 and portions of the lower dielectric layer 104. The second metal layer 147 includes a different material than the first metal layer 145 and is disposed on an uppermost surface of the first metal layer 145. The gate cut portions 160-1 and 160-2 are disposed through part of their corresponding gate structures 115-1 and 115-2. The source/drain contact structures are disposed around (e.g., on sides of) the gate cut portions 160-1 and 160-2.

In illustrative embodiments, the uppermost surface of the first metal layers 145 are coplanar with uppermost surfaces of the SAC cap layers 120. As can be seen in FIG. 10D, the gate cut portion 160-2 is disposed through a part of an SAC cap layer 120 and a part of the additional dielectric layer 135. A top surface of the gate cut portion 160-2 is coplanar with a top surface of the additional dielectric layer 135. As can be seen in FIG. 10B, the top surfaces of the gate cut portions 160-1 and 160-2 are coplanar with top surfaces of the second metal layer 147. Also referring to FIG. 10B, the lower dielectric layer 104 (e.g., shallow trench isolation (STI) region) is disposed between the gate cut portion 160-1 corresponding to a gate structure 115-1 of a first transistor and the gate cut portion 160-2 corresponding to a gate structure 115-1 of a second transistor. Parts of the gate cut portions 160-1 and 160-2 are disposed through the lower dielectric layer 104 into the underlying semiconductor substrate 101.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. An example integrated circuit includes one or more semiconductor devices with the above-described diffusion break structure.

As noted above, illustrative embodiments correspond to formation of a gate cut structure for a semiconductor device where a source/drain contact structure formed around the gate structure includes a first metal layer and second metal cap layer, along with illustrative apparatus, systems and devices formed using such methods. The gate cut structure is formed after source/drain contact formation. The source/drain contact includes a first metal layer in proximity to the source/drain epitaxial material and a second metal layer serving as a cap, which has a different composition than that of the first metal layer. The STI region between two consecutive transistors is continuous and extends from one gate cut portion to another gate cut portion. For example, referring to FIG. 10B, the lower dielectric layer 104 (e.g., STI region) that is disposed between gate cut portion 160-1 and 160-2 is continuous, whereby a first end of the lower dielectric layer 104 contacts the gate cut portion 160-1 and a second end of the lower dielectric layer 104 contacts the gate cut portion 160-2. The gate cut processing after source/drain contact formation in accordance with the illustrative embodiments is compatible with self-aligned S/D contact etching such that there are no stringent overlay and critical dimension requirements for source/drain contact etching.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
at least one transistor comprising a gate structure and a source/drain region;
a source/drain contact structure disposed on the source/drain region, wherein the source/drain contact structure comprises a first metal layer and second metal layer disposed on the first metal layer, and wherein the second metal layer comprises a different material than the first metal layer and is disposed on an uppermost surface of the first metal layer; and
a gate cut portion disposed through a part of the gate structure, wherein the source/drain contact structure is disposed on a side of the gate cut portion.

2. The semiconductor device of claim 1, further comprising a self-aligned contact cap layer disposed on the gate structure, wherein the uppermost surface of the first metal layer is coplanar with an uppermost surface of the self-aligned contact cap layer.

3. The semiconductor device of claim 1, further comprising a self-aligned contact cap layer disposed on the gate structure, wherein the gate cut portion is disposed through a part of the self-aligned contact cap layer.

4. The semiconductor device of claim 3, further comprising a dielectric layer disposed on the self-aligned contact cap layer, wherein the gate cut portion is disposed through a part of the dielectric layer.

5. The semiconductor device of claim 4, wherein a top surface of the gate cut portion is coplanar with a top surface of the dielectric layer.

6. The semiconductor device of claim 1, wherein a top surface of the gate cut portion is coplanar with a top surface of the second metal layer.

7. The semiconductor device of claim 1, further comprising:
at least one additional transistor comprising an additional gate structure and an additional source/drain region;
an additional gate cut portion disposed through a part of the additional gate structure; and
an isolation region disposed between the gate cut portion and the additional gate cut portion.

8. The semiconductor device of claim 7, wherein respective parts of the gate cut portion and the additional gate cut portion are disposed through the isolation region.

9. The semiconductor device of claim 7, wherein the isolation region is disposed under a portion of the source/drain contact structure.

10. The semiconductor device of claim 7, wherein the isolation region comprises a shallow trench isolation region.

11. The semiconductor device of claim 1, wherein the gate cut portion comprises a dielectric material.

12. A semiconductor device, comprising:
a gate cut portion disposed through a gate structure; and
a source/drain contact structure disposed around the gate cut portion, wherein the source/drain contact structure comprises a first metal layer and second metal layer disposed on the first metal layer, and wherein the second metal layer comprises a different material than the first metal layer and is disposed on an uppermost surface of the first metal layer.

13. The semiconductor device of claim 12, further comprising a self-aligned contact cap layer disposed on the gate structure, wherein the uppermost surface of the first metal layer is coplanar with an uppermost surface of the self-aligned contact cap layer.

14. The semiconductor device of claim 12, further comprising a self-aligned contact cap layer disposed on the gate structure, wherein the gate cut portion is disposed through a part of the self-aligned contact cap layer.

15. The semiconductor device of claim 12, further comprising:
an additional gate cut portion disposed through an additional gate structure; and
an isolation region disposed between the gate cut portion and the additional gate cut portion.

16. The semiconductor device of claim 15, wherein respective parts of the gate cut portion and the additional gate cut portion are disposed through the isolation region.

17. The semiconductor device of claim 15, wherein the isolation region is disposed under the source/drain contact structure.

18. A semiconductor device, comprising:
a first gate cut portion disposed through a first gate structure;
a second gate cut portion disposed through a second gate structure; and
a source/drain contact structure disposed around the first gate cut portion and the second gate cut portion, wherein the source/drain contact structure comprises a first metal layer and second metal layer disposed on the first metal layer, and wherein the second metal layer comprises a different material than the first metal layer and is disposed on an uppermost surface of the first metal layer.

19. The semiconductor device of claim 18, further comprising an isolation region disposed between the first gate cut portion and the second cut gate portion.

20. The semiconductor device of claim 19, wherein the isolation region is disposed under the source/drain contact structure.
